(19) United States
(12) Patent Application Publication
(10) Pub. No.: US 2025/0244259 A1
(43) Pub. Date: Jul. 31, 2025

(54) SEMICONDUCTOR INSPECTION APPARATUS AND METHOD OF MANUFACTURING SEMICONDUCTOR DEVICE USING THE SAME

(71) Applicant: SAMSUNG ELECTRONICS CO., LTD., Suwon-si (KR)

(72) Inventors: Yongwoon KIM, Suwon-si (KR); Donhwan LEE, Suwon-si (KR); Wooseok HEO, Suwon-si (KR); Jiyeon KIM, Suwon-si (KR); Suyoung LEE, Suwon-si (KR); Hyeongcheol Lee, Suwon-si (KR)

(73) Assignee: SAMSUNG ELECTRONICS CO., LTD. Suwon-si, Suwon-si (KR)

(21) Appl. No.: 18/949,205

(22) Filed: Nov. 15, 2024

(30) Foreign Application Priority Data
Jan. 25, 2024 (KR) 10-2024-0011727

(51) Int. Cl. G01N 21/95; G01N 21/88; H01L 21/66

(52) U.S. Cl. CPC G01N 21/9505; G01N 21/8806; H01L 22/12; G01N 2021/8835

(57) ABSTRACT

Provided is a semiconductor inspection device. The semiconductor inspection device includes a laser light source configured to generate a laser beam that is scanned onto a semiconductor substrate, a first optical system spaced apart from a top surface of the semiconductor substrate in a vertical direction and configured to concentrate the laser beam on a confocal point, a semiconductor substrate stage arranged on one side of the semiconductor substrate and configured to move the semiconductor substrate in the vertical direction, a detector configured to measure a Raman signal from the laser beam scattered from the semiconductor substrate, and a controller configured to calculate a Raman spectrum through the Raman signal measured from the detector and pieces of peak signal data of amorphous silicon and crystalline silicon included in channel layers from the Raman spectrum and measure a degree of crystallinity based on a depth of the semiconductor substrate.

### CROSS-REFERENCE TO RELATED APPLICATION

This application is based on and claims priority under 35 U.S.C. § 119 to Korean Patent Application No. 10-2024-0011727, filed on Jan. 25, 2024, in the Korean Intellectual Property Office, the disclosure of which is incorporated by reference herein in its entirety.

### BACKGROUND

The present disclosure relates to a semiconductor inspection device and a method of manufacturing a semiconductor device by using the same.

An example of a process for manufacturing a semiconductor device is a metal-induced lateral crystallization process. In the case of a metal-induced lateral crystallization process, in determining crystallinity, which is a measure of progress, a sample for a transmission electron microscope (TEM) should be produced by destroying a semiconductor substrate, but loss of substrate and loss of a process time occurs. Accordingly, various technologies for non-destructive testing have are needed to optimize metal-induced lateral crystallization processes.

### SUMMARY

The present disclosure provides a semiconductor inspection device with improved reliability.

The present disclosure provides a method of manufacturing a semiconductor device through a semiconductor inspection device with improved reliability.

According to an aspect of the present disclosure, there is provided a semiconductor inspection device including a laser light source configured to generate a laser beam that is scanned onto a semiconductor substrate, a first optical system spaced apart from a top surface of the semiconductor substrate in a vertical direction, a semiconductor substrate stage arranged on one side of the semiconductor substrate and configured to move the semiconductor substrate in the vertical direction, a detector configured to measure a Raman signal from the laser beam scattered from the semiconductor substrate, and a controller configured to calculate a Raman spectrum through the Raman signal measured from the detector, wherein the semiconductor substrate comprises a plurality of channel layers, the first optical system is configured to concentrate the laser beam on a confocal point, and the controller is configured to extract one or more pieces of peak signal data of amorphous silicon and crystalline silicon included in the channel layers from the Raman spectrum and measure a degree of crystallinity based on a depth of the semiconductor substrate.

According to another aspect of the present disclosure, there is provided a semiconductor inspection device including a semiconductor substrate including a plurality of channel layers, a semiconductor substrate stage arranged on a bottom surface of the semiconductor substrate and moving the semiconductor substrate in a vertical direction, a laser light source configured to generate a laser beam that is scanned onto the semiconductor substrate, a first optical system spaced apart from a top surface of the semiconductor substrate in the vertical direction and configured to concentrate the laser beam at a confocal point, a pin hole configured to allow a Raman signal to pass through the pin hole and block a noise signal, wherein the Raman signal is a laser beam scanned and scattered at the confocal point, and wherein the noise signal is a laser beam scanned and scattered at a point deviated from the confocal point, a detector arranged at a position above the pin hole and configured to measure the Raman signal, and a controller configured to calculate a Raman spectrum through the Raman signal measured from the detector, wherein the channel layers include amorphous silicon and crystalline silicon, and the controller may extract peak signal data of the amorphous silicon and peak signal data of the crystalline silicon from among the Raman spectrum, and measure a degree of crystallinity based on a depth of the semiconductor substrate.

According to another aspect of the present disclosure, there is provided a method of manufacturing a semiconductor device, the method including preparing a semiconductor substrate, performing a semiconductor process on the semiconductor substrate, inspecting a semiconductor generated through the semiconductor process through a semiconductor inspection device, and performing a subsequent semiconductor process on the semiconductor substrate, wherein the semiconductor inspection device includes a laser light source configured to generate a laser beam that is scanned onto the semiconductor substrate, a first optical system spaced apart from a top surface of the semiconductor substrate in a vertical direction and configured to concentrate the laser beam at a confocal point, a semiconductor substrate stage arranged on one side of the semiconductor substrate and configured to move the semiconductor substrate in the vertical direction, a detector configured to measure a Raman signal from the laser beam scattered from the semiconductor substrate, and a controller configured to calculate a Raman spectrum through the Raman signal measured from the detector, wherein the semiconductor substrate includes a plurality of channel layers, and the controller configured to extract one or more pieces of peak signal data of amorphous silicon and crystalline silicon included in the channel layers, from among the Raman spectrum, calculate a ratio of a first peak signal data of crystalline silicon to a second peak signal data of amorphous silicon based on a depth of the semiconductor substrate, and extract a degree of crystallinity by calculating a signal intensity based on a depth of a metal layer from the ratio.

### BRIEF DESCRIPTION OF DRAWINGS

Embodiments of the present disclosure will be more clearly understood from the following detailed description taken in conjunction with the accompanying drawings in which:

FIG. 1 is a diagram of a semiconductor inspection device according to an embodiment;

FIG. 2 is a diagram illustrating a method or process of performing an inspection of a semiconductor inspection device, according to an embodiment;

FIG. 3 is an enlarged view of a region A of FIG. 2;

FIG. 4 is an enlarged view of a region B of FIG. 2;

FIG. 5 is a cross-sectional view illustrating a degree of crystallinity of a semiconductor substrate according to an embodiment;

FIG. 6 is a graph illustrating intensity of a signal with respect to wavenumber of a semiconductor inspection device according to a degree of crystallinity, according to an embodiment;

FIG. 7 is a graph illustrating silicon ratio according to depth of a semiconductor substrate of a semiconductor inspection device according to a degree of crystallinity, according to an embodiment;

FIG. 8 is a graph illustrating the strength of a metal layer signal at the bottom portion of a semiconductor substrate of a semiconductor inspection device according to a degree of crystallinity, according to an embodiment;

FIG. 9 is a flowchart of a method of manufacturing a semiconductor device, according to an embodiment; and

FIG. 10 is a flowchart of a semiconductor inspection method according to an embodiment.

### DETAILED DESCRIPTION

Since the present embodiments may be modified in various ways and may have various forms, some embodiments are illustrated in the drawings and described in detail. However, it is not intended to limit the present embodiments to the particular disclosed forms. In addition, embodiments described below are merely illustrative, and various modifications are possible from these embodiments.

The use of all examples or example terms is merely intended to describe the technical idea in detail and is not intended to be limiting in scope by such examples or example terms, unless being limited by the claims.

Hereinafter, unless otherwise specified, in the present disclosure, a vertical direction may be defined in a Z direction, and a first direction and a second direction may be defined in a horizontal directions perpendicular to a Z direction, respectively. The first direction may be referred to as X, and the second direction may be referred to as Y. A vertical level may refer to a height level according to the vertical direction Z. A horizontal width may refer to a length in the horizontal direction X and/or Y, and a vertical length may refer to a length in the vertical direction Z.

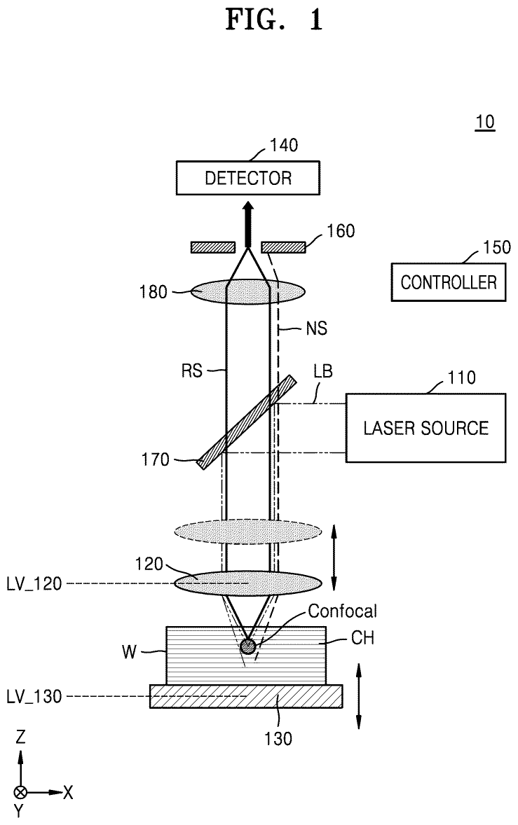

FIG. 1 is a diagram of a semiconductor inspection apparatus 10 according to an embodiment.

Referring to FIG. 1, a semiconductor inspection apparatus 10 may measure a degree of crystallinity with respect to a semiconductor substrate W by depth. The semiconductor inspection apparatus 10 may include a laser light source 110 that generates a laser beam LB scanned on a semiconductor substrate. There may be a plurality of laser light sources 110 from which the laser beams LB are emitted. The wavelength band of the laser beam LB may be infrared rays, visible rays, or ultraviolet rays, but may be formed differently depending on the type and size of the semiconductor substrate W. The semiconductor substrate W may include a plurality of channel layers CH.

The semiconductor substrate W may include a semiconductor material. For example, the semiconductor substrate W may be a silicon substrate doped with n-type impurities. However, this is only an example, and the semiconductor substrate W may include, for example, a group IV semiconductor material such as germanium (Ge), silicon germanium (SiGe), or silicon carbide (SiC), a group III-V semiconductor material such as gallium arsenic (GaAs), indium arsenic (InAs), or indium phosphide (InP), oxide semiconductor, nitride semiconductor, oxynitride semiconductor, etc. However, embodiments are not limited thereto. In some embodiments, the semiconductor substrate W may be a silicon-on-insulator (SOI) substrate or a germanium-on-insulator (GOI) substrate. A gate insulating layer may include silicon oxide.

In some embodiments, the channel layer CH may include a semiconductor material. For example, the channel layer CH may include single crystal silicon or polysilicon. In some other embodiments, the channel layer CH may include an oxide semiconductor material. The channel layer CH may include at least one of a binary or ternary oxide semiconductor material including a first metal element, a ternary oxide semiconductor material including a first metal element and a second metal element different from each other, and a quaternary oxide semiconductor material including a first metal element, a second metal element, and a third metal element different from one another. For example, the binary or ternary oxide semiconductor material may be one of, but is not limited to, zinc oxide (ZnO or ZnxO), gallium oxide (GaO or GaxO), tin oxide (TiO or TixO), zinc oxynitride (ZnON or ZnxOyN), indium zinc oxide (IZO or InxZnyO), gallium zinc oxide (GZO or GZnO), tin zinc oxide (TZO or SnxZnyO), and tin gallium oxide (TGO or SnxGayO). Here, x and y are positive integers. For example, the quaternary oxide semiconductor material may be one of, but is not limited to, indium gallium zinc oxide (IGZO or InxGayZnzO), indium gallium silicon oxide (IGSO or InxGaySizO), indium tin zinc oxide (ITZO or InxSnyZnzO), indium gallium tin oxide (IGTO or InzGaySnzO), zirconium zinc tin oxide (ZZTO or ZrxZnySnzO), hafnium indium zinc oxide (HIZO or HfxInyZnzO), gallium zinc tin oxide (GZTO or GaxZnySnzO), aluminium zinc tin oxide (AZTO or AlxZnySnzO), yttrium gallium zinc oxide (YGZO or YbxGayZnzO), and indium aluminum zinc oxide (IAZO or InxAlyZnzO). Here, x, y, and z are positive integers.

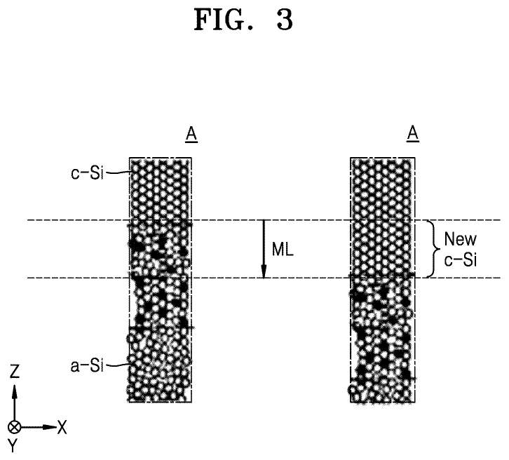

In some embodiments, the channel layer CH may include a crystalline oxide semiconductor material or an amorphous oxide semiconductor material. When the channel layer CH includes a crystalline oxide semiconductor material, the channel layer CH may have at least one of single crystalline, polycrystalline, spinel, and c-axis aligned crystalline (CAAC). In some embodiments, the channel layer CH may be formed by stacking at least two layers including a first layer made of a crystalline oxide semiconductor material and a second layer made of an amorphous oxide semiconductor material. For example, the channel layer CH may be formed by sequentially stacking a first layer made of a crystalline oxide semiconductor material, a second layer made of an amorphous oxide semiconductor material, and a third layer made of a crystalline oxide semiconductor material. The channel layers CH included in the semiconductor substrate W may be formed by metal-induced lateral crystallization (MILC). The metal-induced side crystallization (MILC) will be described in detail in FIGS. 3 to 5.

The semiconductor inspection apparatus 10 may include a first optical system 120 arranged to be spaced apart from the top surface of the semiconductor substrate W in the vertical direction Z. The first optical system 120 may move in the vertical direction Z. The distance between the first optical system 120 and the top surface of the semiconductor substrate W may be formed differently depending on properties such as the thickness of the semiconductor substrate W. In an embodiment, the first optical system 120 may be configured such that the confocal point of the laser beam LB is formed inside the semiconductor substrate W. Here, the confocal point means a point where light for a laser beam LB or another light source is condensed at a specific point in a Raman optical system. When the laser beam LB is condensed at the confocal point, the performance of the measurement system may be optimized, and the laser beam LB is concentrated on an object to be measured, thereby enabling precise measurement. The confocal point may be formed through a lens or a mirror in an optical system. Embodiments of the present disclosure describe in detail an exemplary case when only a lens forms a focus by refracting a laser beam LB. The first optical system 120 may include a mirror to form a confocal point. In an embodiment, the first optical system 120 may include at least one convex lens. The first optical system 120 may include an infrared filter. The infrared filter may be used to obtain an accurate Raman spectrum by minimizing interference from light rays other than the laser beam LB. However, when a desired wavelength band is an ultraviolet region other than infrared rays, an ultraviolet filter may be included.

The semiconductor inspection apparatus 10 may include a semiconductor substrate stage 130 arranged on one side of the semiconductor substrate W and moving the semiconductor substrate W in the vertical direction Z. In an embodiment, the semiconductor substrate stage 130 may be arranged on the bottom surface of the semiconductor substrate W.

The semiconductor inspection apparatus 10 may include a controller 150. The first optical system 120 and the semiconductor substrate stage 130 may move in the vertical direction Z, and a vertical level of each of the first optical system 120 and the semiconductor substrate stage 130 may be controlled by the controller 150. The first optical system 120 may move in the vertical direction Z to correspond to a vertical level LV_130 of the semiconductor substrate stage 130. A vertical level LV_120 of the first optical system 120 may be higher than the vertical level LV_130 of the semiconductor substrate stage 130. The vertical level LV_120 of the first optical system and the vertical level LV_130 of the semiconductor substrate stage may be spaced apart from each other, and the spaced distance may be formed differently according to the type of the semiconductor substrate W. When the vertical level LV_120 of the first optical system and the vertical level LV_130 of the semiconductor substrate stage are changed, the depth of the semiconductor substrate W corresponding to the confocal point may be changed.

The semiconductor inspection apparatus 10 may further include a mirror 170 arranged on the path of the laser beam LB of the laser light source 110 and configured to change the path of travel of the laser beam LB. In an embodiment, the mirror 170 may include a planar mirror.

The laser beam LB generated from the laser light source 110 may be reflected from the mirror 170, and the laser beam LB reflected from the mirror 170 may be condensed by the first optical system 120 and scanned onto the semiconductor substrate W. Some of the laser beams LB may be concentrated into the confocal point, and the rest may not be concentrated into the confocal point. The laser beam LB may be reflected or scattered after being scanned on the semiconductor substrate W. The plurality of vertically stacked channel layers CH may be scanned by the laser beam LB for each level. When the laser beams LB scattered from the semiconductor substrate W are concentrated at the confocal point, the laser beams LB concentrated at the confocal point may be defined as Raman signals RS. When the laser beams LB scattered from the semiconductor substrate W are not concentrated at the confocal point, the laser beams LB not concentrated at the confocal point may be defined as noise signals NS.

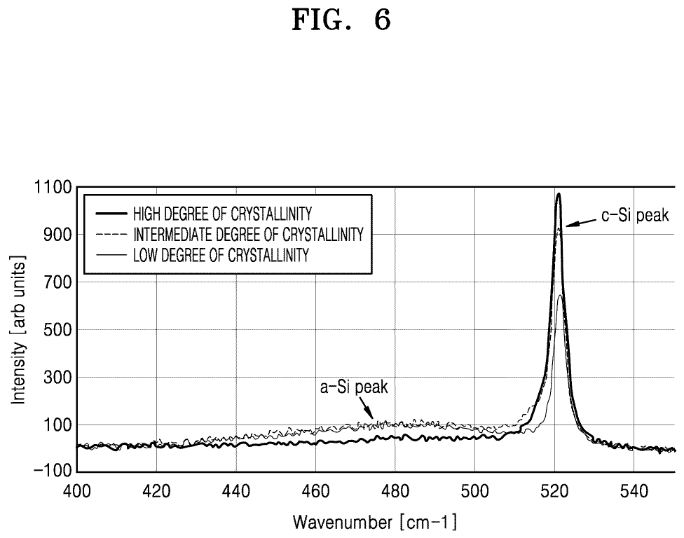

The semiconductor inspection apparatus 10 may include a detector 140 that measures the Raman signal RS of the laser beams LB scattered from the semiconductor substrate. The detector 140 may be arranged on the path of travel of the Raman signal RS. The controller 150 may calculate the Raman spectrum through the Raman signal RS measured from the detector 140. The Raman spectrum will be described in detail with reference to FIGS. 6 to 9.

The Raman signal RS may be generated by scattering the laser beam LB concentrated at the confocal point. The Raman signal RS may include information on a component of the channel layer CH on which the confocal point is located. In an embodiment, the Raman signal RS may include, as the strength of the signal for each component, information on the component of the channel layer CH on which the confocal point is located. The channel layer CH may include amorphous silicon and crystalline silicon. In an embodiment, the signal of the component of the channel layer CH included in the Raman signal RS may include peak signal data of amorphous silicon and peak signal data of crystalline silicon. The channel layer CH may include a metal layer. In an embodiment, the signal of the component of the channel layer CH included in the Raman signal RS may be signal data for the metal layer. The magnitude of a peak value of each signal data may be proportional to the content of each component in a region where the confocal point is located. The Raman signal RS may be detected by depth of the semiconductor substrate W, and signal strength may be measured by depth. That is, after the strength of the signal is measured by depth, the controller 150 may collect the data to form a Raman spectrum.

The noise signal NS may be generated by scattering the laser beam LB concentrated in a non-confocal region. Unlike the Raman signal RS, the noise signal NS may not include accurate information on a region to be measured. Therefore, when the controller 150 forms the Raman spectrum, the noise signal may correspond to unnecessary information. The semiconductor inspection apparatus 10 may include a pin hole 160 arranged under the detector 140. The pin hole 160 may pass only the Raman signal RS scanned and scattered at the confocal point. The pin hole 160 may block the noise signal NS scanned and scattered at a point outside the confocal point. When viewed in a plan view, the pin hole 160 may extend in the first direction X and the second direction Y orthogonal to the first direction X, an opening may be formed in the center thereof, and the opening may be circular or polygonal.

The semiconductor inspection apparatus 10 may include a second optical system 180 arranged on the path of the Raman signal RS and configured to concentrate the Raman signal RS on the detector 140. The second optical system 180 may include at least one lens.

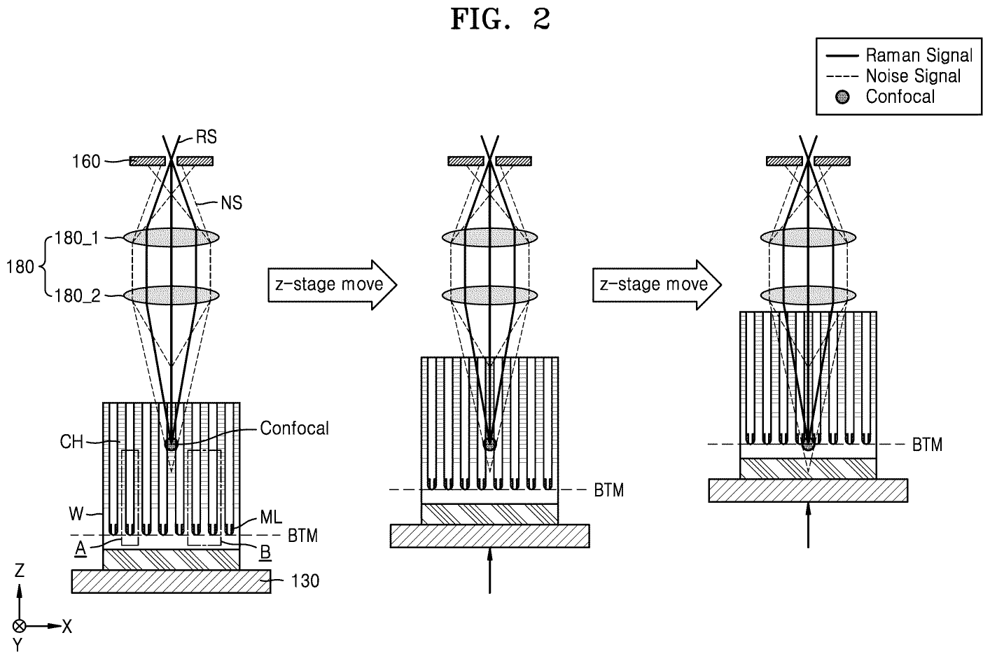

FIG. 2 is a diagram illustrating a method of performing an inspection of a semiconductor inspection device according to an embodiment.

Referring to FIG. 2 together with FIG. 1, the second optical system 180 included in the semiconductor inspection apparatus 10 may include at least one lens, and as an example, may include two lenses 180_1 and 180_2. Each of the lenses 180_1 and 180_2 may be a convex lens. Each of the lenses 180_1 and 180_2 may be configured to condense Raman signals RS.

The semiconductor substrate W may include metal layers ML. Since crystalline silicon is crystallized while descending in the vertical direction, a degree of crystallinity of the semiconductor substrate W may be higher as the metal layers ML approaches a bottom (BTM). In order to accurately detect the degree of crystallinity, the semiconductor substrate stage 130 may move in the vertical direction Z. Components, such as the pin hole 160, the second optical system 180, and the detector 140, may not move in the vertical direction. A vertical level of the confocal point Confocal of the laser beam LB generated by the laser light source 110 may be constant. However, even in this case, if the first optical system 120 moves in the vertical direction as shown in FIG. 1, the vertical level of the confocal point may be moved accordingly.

The confocal point may be formed at a level higher than the vertical level of the bottom BTM. The semiconductor substrate stage 130 may rise or fall to a point where the vertical level of the confocal point coincides with the vertical level of the bottom BTM. FIG. 2 shows only the cases when the semiconductor substrate stage 130 rises.

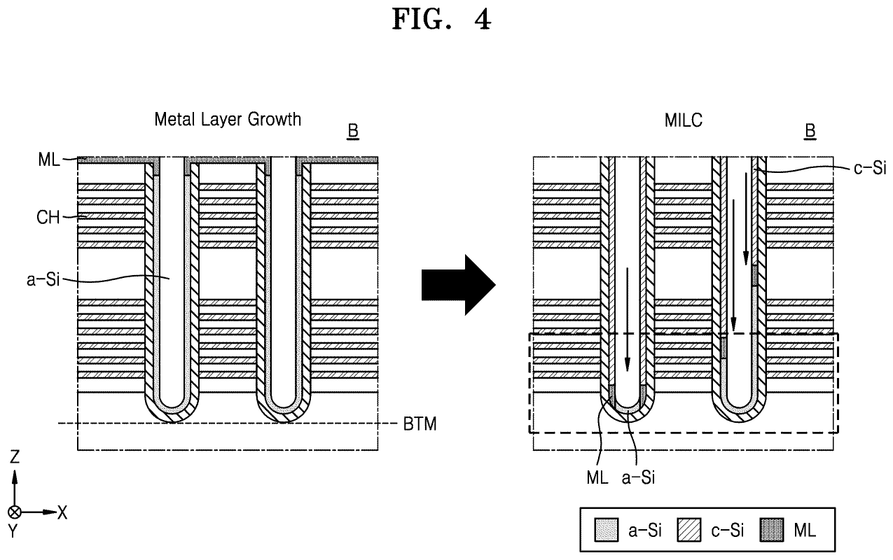

FIG. 3 is an enlarged view of a region A of FIG. 2. FIG. 4 is an enlarged view of a region B of FIG. 2. a-Si shown in the drawings means amorphous silicon. c-Si shown in the drawings means crystalline silicon.

Referring to FIGS. 3 and 4 together with FIGS. 1 and 2, the channel layers may be formed by metal-induced lateral crystallization (MILC). More specifically, amorphous silicon may be arranged in a region in which crystallization is performed. Thereafter, amorphous silicon arranged on the side surface may be transformed into crystalline silicon. Although amorphous silicon is not shown in the drawings, the amorphous silicon may be placed between a source and a drain. Referring to FIG. 4, a metal layer ML may be applied on amorphous silicon thereafter. The metal layer ML may include at least one of nickel (Ni), aluminum (Al), titanium (Ti), and alloys thereof. The metal layer ML may perform a function of inducing crystallization of amorphous silicon. Thereafter, a heat treatment process may be performed by applying heat to a semiconductor device. When applying heat, the overall component is heated to a high temperature, resulting in crystallization between the metal layer (ML) and amorphous silicon. Although the crystallization proceeding direction may vary from process to process, in an embodiment according to the present disclosure, crystallization of amorphous silicon proceeds while the metal layer ML descends in the vertical direction as shown in FIGS. 3 and 4. As crystallization proceeds between the metal layer ML and amorphous silicon, crystallization proceeds in an region in which the metal layer ML passes in the vertical direction so that newly formed crystalline silicon may be arranged in the region. Referring to FIG. 4, the metal layer ML may perform crystallization while descending in the vertical direction to the bottom BTM. Therefore, when the crystallization progress is completed and the degree of crystallinity is the highest, the metal layer ML may be located at the bottom BTM.

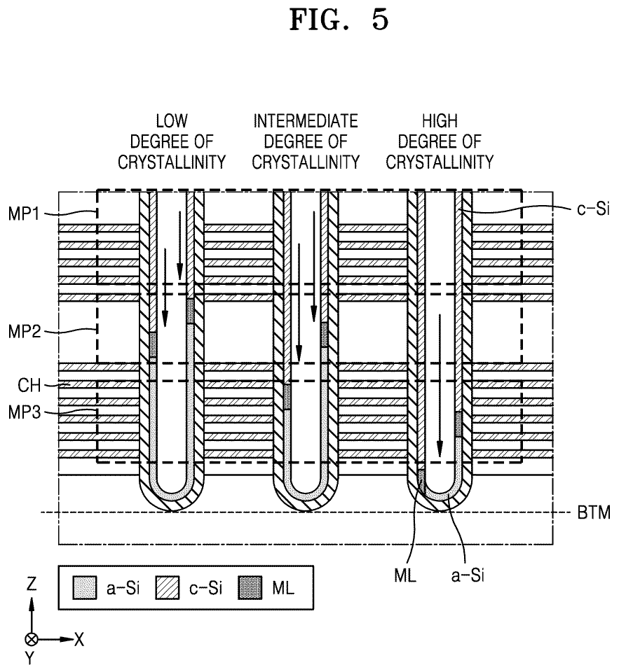

FIG. 5 is a cross-sectional view illustrating a degree of crystallinity of a semiconductor substrate according to an embodiment.

Referring to FIG. 5 together with FIGS. 1 to 4, the semiconductor inspection apparatus 10 may repeat measurement by depth for a plurality of vertically stacked channel layers CH. In an embodiment, respective measurements may be performed at a first measurement point MP1 having the highest vertical level, a second measurement position MP2 having a lower vertical level than the first measurement position MP1, and a third measurement position MP3 having the lowest level. The plurality of measurement positions may correspond to positions of the confocal point. The inspection may be performed by sequentially scanning the laser beam LB from the first measurement position MP1 to the third measurement position MP3.

FIG. 5 shows sequentially increasing degrees of crystallinity from the left according to the degree of crystallinity. More specifically, the leftmost case shows a state in which a degree of crystallinity is low, the middle case shows a state in which a degree of crystallinity is intermediate, and the rightmost case shows a state in which a degree of crystallinity is high. As described with reference to FIGS. 2 and 3, the lower the vertical level of the metal layer ML, the higher the degree of crystallinity. That is, the degree of crystallinity may be proportional to the signal strength with respect to the metal layer ML located on the bottom BTM of the semiconductor substrate W.

In an embodiment, it is assumed that the Raman signal RS is analyzed by scanning a laser beam LB at the first measurement position MP1. In all three cases, only peak signal data of crystalline silicon may be obtained. In the first measurement position MP1, amorphous silicon or a metal layer ML is not arranged in all three cases.

In an embodiment, it is assumed that the Raman signal RS is analyzed by scanning a laser beam LB at the second measurement position MP2.

When the degree of crystallinity is high, only peak signal data of crystalline silicon may be obtained. This is because amorphous silicon or the metal layer ML is not arranged at the second measurement position MP2.

When the degree of crystallinity is intermediate, not only the peak signal data of crystalline silicon but also the peak signal data of the metal layer ML and the peak signal data of amorphous silicon may be obtained. A ratio of peak signal data of crystalline silicon to peak signal data of amorphous silicon may be calculated through the controller 150, and the degree of crystallinity may be measured based on the calculated value. A description thereof is given in FIGS. 6 to 8.

When the degree of crystallinity is low (e.g., at first measurement position MP1), not only the peak signal data of crystalline silicon but also the peak signal data of the metal layer ML and the peak signal data of amorphous silicon may be obtained. However, the ratio of the peak signal data of crystalline silicon to the peak signal data of amorphous silicon may be lower than the ratio in the case where the degree of crystallinity is intermediate (e.g., at second measurement position MP2). This is because the ratio of amorphous silicon is higher in the leftmost case than in the intermediate case. In other words, this is because the ratio of crystalline silicon is lower in the leftmost case than in the intermediate case.

In an embodiment, it is assumed that the Raman signal RS is analyzed by scanning a laser beam LB at the third measurement position MP3. The third measurement position MP3 is the measurement position closest to the bottom BTM.

When the degree of crystallinity is high (e.g., at third measurement position MP3), not only the peak signal data of crystalline silicon but also the peak signal data of the metal layer ML and the peak signal data of amorphous silicon may be obtained. A ratio of peak signal data of crystalline silicon to peak signal data of amorphous silicon may be calculated through the controller 150, to thus calculate the degree of crystallinity. Alternatively, independently of the calculated ratio, since the third measurement position MP3 is the closest measurement position to the bottom BTM, the degree of crystallinity may be calculated by measuring the peak signal data of the metal layer ML.

When the degree of crystallinity is intermediate, not only the peak signal data of crystalline silicon but also the peak signal data of the metal layer ML and the peak signal data of amorphous silicon may be obtained. A ratio of peak signal data of crystalline silicon to peak signal data of amorphous silicon may be calculated through the controller 150. However, the ratio of the peak signal data of crystalline silicon to the peak signal data of amorphous silicon may be lower than the ratio in the rightmost case where the degree of crystallinity is high. This is because the ratio of amorphous silicon is higher in the intermediate case than in the rightmost case. In other words, this is because the ratio of crystalline silicon is lower in the intermediate case than in the rightmost case. In addition, alternatively, independent of the calculated ratio, the third measurement position MP3 is the closest measurement position to the bottom BTM, and thus, when the peak signal data of the metal layer ML is measured, the peak signal data in the intermediate case is lower than the peak signal data in the rightmost case.

When the degree of crystallinity is low, only peak signal data of amorphous silicon may be obtained. This is because the crystalline silicon or the metal layer ML is not arranged at the second measurement position MP2.

FIG. 6 is a graph illustrating an intensity of a signal with respect to a wave number of a semiconductor inspection device based on a degree of crystallinity according to an embodiment.

Referring to FIG. 6, after measuring the semiconductor substrate W by depth, the Raman spectrum may be secured through the Raman signal RS by section of the depth. In the graph, the X-axis represents a wavenumber, and the wave number represents a wavenumber with respect to the laser beam LB. In an embodiment, the peak signal data of amorphous silicon is generated in the range of about 470 cm⁻¹ to about 480 cm⁻¹. The peak signal data of crystalline silicon is generated in the range of about 510 cm⁻¹ to about 530 cm⁻¹. Depending on the type of amorphous silicon and crystalline silicon, a range in which the peak signal data is generated may be formed differently. The higher the degree of crystallinity, the lower the peak signal data of amorphous silicon generated in the range of about 470 cm⁻¹ to about 480 cm⁻¹, and the higher the peak signal data of crystalline silicon generated in the range of about 510 cm⁻¹ to about 530 cm⁻¹. The lower the degree of crystallinity, the higher the peak signal data of amorphous silicon generated in the range of about 470 cm⁻¹ to about 480 cm⁻¹, and the lower the peak signal data of crystalline silicon generated in the range of about 510 cm⁻¹ to about 530 cm⁻¹.

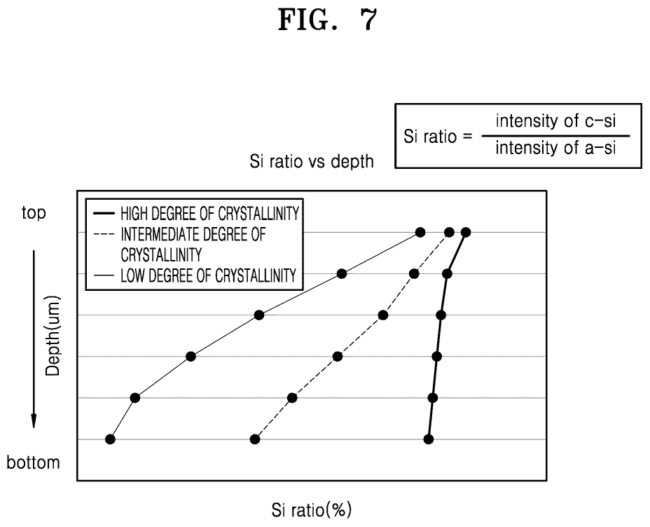

FIG. 7 is a graph illustrating a ratio of silicon depending on a depth of a semiconductor substrate of a semiconductor inspection device based on a degree of crystallinity according to an embodiment.

Referring to FIG. 7 together with FIGS. 1 to 6, the ratio of different types of silicon included in the channel layer CH may be calculated as in Equation 1.

$$Si ratio = \frac{intensity of c - s i}{intensity of a - s i} \qquad [ Equation 1 ]$$

In Equation 1, c-si means crystalline silicon, and the numerator means the intensity of peak signal data of crystalline silicon. a-si means amorphous silicon, and denominator means the intensity of peak signal data of amorphous silicon. A ratio (i.e., a Si ratio) of different types of silicon may be arranged on the X-axis. The Y-axis represents the depth of the semiconductor substrate W. The unit for the magnitude of the depth may be, for example, micrometers (μm), but is not limited thereto.

When looking at the low degree of crystallinity, the intermediate degree of crystallinity, and the high degree of crystallinity, at the bottom BTM, the ratio (i. e., the Si ratio) of different types of silicon is the highest in the case of the high degree of crystallinity, and the former is the lowest in the case of the low degree of crystallinity. Therefore, the highest degree of crystallinity means that the intensity of the peak signal data of crystalline silicon is high or the intensity of the peak signal data of amorphous silicon is low. The peak signal data of crystalline silicon and the peak signal data of amorphous silicon may be calculated by the controller 150 based on the Raman spectrum data. In other words, the controller 150 may be configured to calculate a ratio of peak signal data of crystalline silicon to peak signal data of amorphous silicon by depth of the semiconductor substrate W, and calculate signal strength by depth of the metal layer based on the ratio, to thereby extract the degree of crystallinity. In addition, as shown in FIGS. 3 to 5, the controller 150 may be configured to indirectly extract the degree of crystallinity by calculating the signal strength by depth of the metal layer ML based on the ratio.

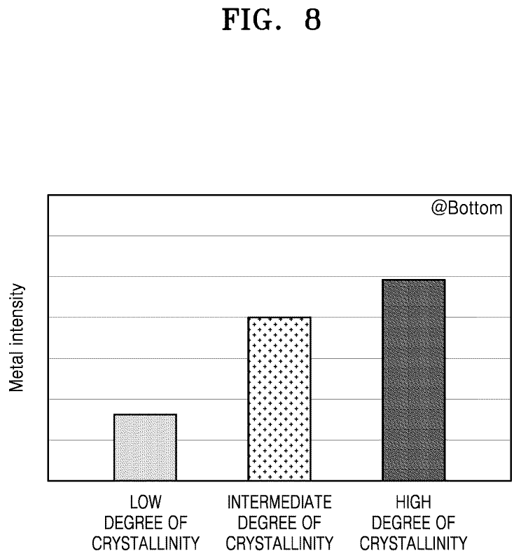

FIG. 8 is a graph illustrating the strength of a metal layer signal at the bottom portion of a semiconductor substrate of a semiconductor inspection device based on a degree of crystallinity according to an embodiment.

Reference is made to FIG. 8 along with FIGS. 1 to 7. The data of the graph shows the strength of the metal layer ML measured at the bottom BTM. It may be seen that the higher the degree of crystallinity, the greater the signal data of the metal layer ML. The strength of the metal layer ML may be extracted by the controller 150. The controller 150 may extract a peak signal of the metal layer ML from the Raman spectrum, and the degree of crystallinity may be proportional to the magnitude of the peak signal of the metal layer ML.

The peak signal data of the metal layer ML may be directly extracted from the Raman spectrum, or may be indirectly extracted from a ratio of peak signal data of crystalline silicon to peak signal data of amorphous silicon by depth of the semiconductor substrate W, which may be calculated by the controller 150. All of the extraction processes may be performed through the controller 150.

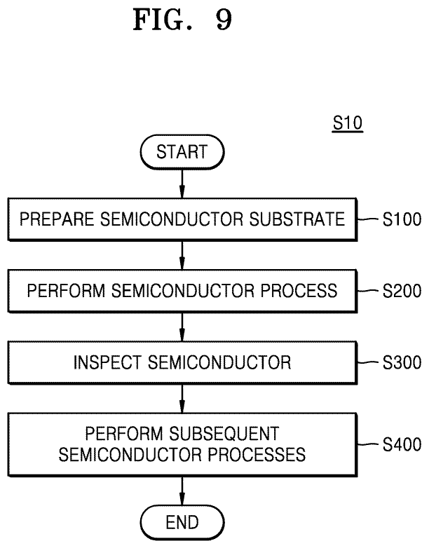

FIG. 9 is a flowchart of a method of manufacturing a semiconductor device according to an embodiment. Reference is made to FIG. 9 along with FIGS. 1 to 8.

Referring to FIG. 9, the semiconductor device manufacturing method S10 may include an operation S100 of preparing the semiconductor substrate W. The semiconductor substrate W may include, for example, a bare wafer on which one or more semiconductor processes have been performed or on which semiconductor processes have not been performed.

Thereafter, the semiconductor device manufacturing method S10 may include an operation S200 of performing a semiconductor process on the semiconductor substrate W. An oxidation process, a photo process, a deposition process, an etching process, an ion process, and/or a cleaning process may be performed on the semiconductor substrate W.

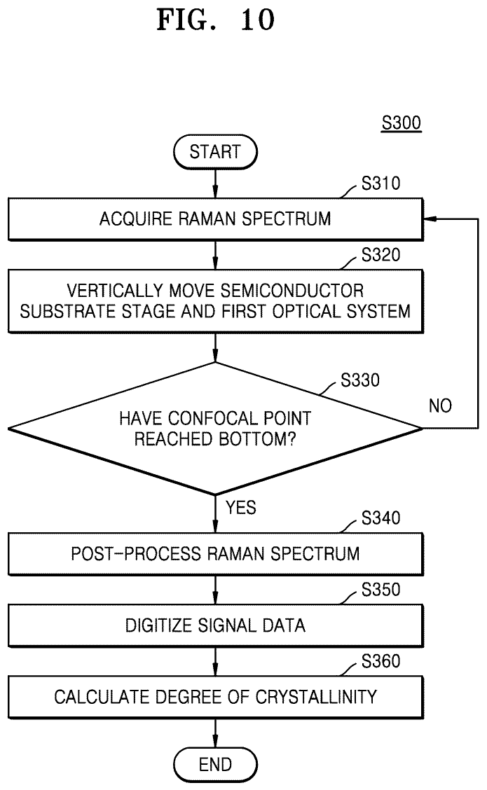

Thereafter, a semiconductor inspection method S300 may be performed. In the operation of performing the semiconductor inspection method S300 of inspecting a semiconductor package, an operation corresponding to the semiconductor inspection method S300 of FIG. 10 may be performed. Operation S300 may be performed by the semiconductor inspection apparatus 10 of FIG. 1.

Thereafter, a subsequent semiconductor process for the semiconductor substrate W is performed (S400). Subsequent semiconductor processes for the semiconductor substrate W may include various processes. For example, the subsequent semiconductor processes may include a singulation process in which the semiconductor substrate W is individualized into each semiconductor chip, a test process in which semiconductor chips are tested, and the like. A semiconductor device may be completed through the subsequent semiconductor processes on the semiconductor substrate W.

FIG. 10 is a flowchart of a semiconductor inspection method according to an embodiment.

Referring to FIG. 10 together with FIGS. 1 to 9, the semiconductor inspection method S300 is an operation of measuring the degree of crystallinity by depth of the semiconductor substrate W. Operation S300 may include an operation S310 of acquiring a Raman spectrum for the semiconductor substrate W through the detector 140 and the controller 150. Operation S300 may include a vertical-direction (Z) movement operation S320 of the semiconductor substrate stage 130 and the first optical system 120. Operation S300 may include an operation S330 of determining whether the confocal point generated by the first optical system 120 has reached the bottom BTM of the semiconductor substrate W. When the confocal point reaches the bottom, an operation S340 of post-processing the Raman spectrum through the controller 150 may be included. As an example, the post-processing may include a peak deconvolution step. Peak deconvolution is used in spectral analysis and refers to an operation of separating a plurality of mixed-type signals into individual signals, respectively, and extracting individual components from the respective individual signals. In an embodiment, peak signal data of amorphous silicon, peak signal data of crystalline silicon, and peak signal data of a metal layer ML, which are target signals, may be extracted in the case of peak deconvolution. In an embodiment, the post-processing may include a removal of a background signal, a noise signal, and the like. If the confocal point does not reach the bottom, operation S310 may be repeated.

Operation S300 may include an operation S350 of digitizing each signal data of the Raman spectrum through the controller 150 and an operation S360 of calculating a degree of crystallinity based on the signal data. Operation S350 corresponds to the description given with reference to FIG. 6, and operation S360 corresponds to the description given with reference to FIGS. 7 and 8, and thus will be omitted.

At least one of the components, elements, modules and units (collectively “components” in this paragraph) represented by a block in the drawings such as FIGS. 1, 2, 9 and 10 may use a direct circuit structure, such as a memory, a processor, a logic circuit, a look-up table, etc. that may execute the respective functions through controls of one or more microprocessors or other control apparatuses. Also, at least one of these components may be specifically embodied by a module, a program, or a part of code, which contains one or more executable instructions for performing specified logic functions, and executed by one or more microprocessors or other control apparatuses. Further, at least one of these components may include or may be implemented by a processor such as a central processing unit (CPU), a microprocessor, or the like that performs the respective functions.

Embodiments of the present disclosure have been described above with reference to the accompanying drawings, but the present disclosure is not limited thereto and may be implemented in various different forms. It will be understood that the present disclosure can be implemented in other specific forms without changing the technical concept or gist of the present disclosure. Therefore, it should be understood that the embodiments set forth herein are illustrative in all respects and not limiting.

While the present disclosure has been particularly shown and described with reference to embodiments thereof, it will be understood that various changes in form and details may be made therein without departing from the spirit and scope of the following claims.

What is claimed is:

1. A semiconductor inspection device comprising:
a laser light source configured to generate a laser beam that is scanned onto a semiconductor substrate;
a first optical system spaced apart from a top surface of the semiconductor substrate in a vertical direction;
a semiconductor substrate stage arranged on one side of the semiconductor substrate and configured to move the semiconductor substrate in the vertical direction;
a detector configured to measure a Raman signal from the laser beam scattered from the semiconductor substrate; and
a controller configured to calculate a Raman spectrum through the Raman signal measured from the detector, wherein
the semiconductor substrate comprises a plurality of channel layers,
the first optical system is configured to concentrate the laser beam on a confocal point, and
the controller is configured to extract one or more pieces of peak signal data of amorphous silicon and crystalline silicon included in the channel layers from the Raman spectrum and measure a degree of crystallinity based on a depth of the semiconductor substrate.

2. The semiconductor inspection device of claim 1, wherein the first optical system is configured such that the confocal point of the laser beam is formed inside the semiconductor substrate.

3. The semiconductor inspection device of claim 2, further comprising a pin hole arranged in position lower than the detector, wherein the pin hole is configured to transmit the Raman signal and block a noise signal,
wherein the Raman signal is a first signal that is scanned and scattered at the confocal point, and
wherein the noise signal is a second signal that is scanned and scattered at a point outside the confocal point.

4. The semiconductor inspection device of claim 1, further comprising a mirror arranged on a path of travel of the laser beam and configured to change the path of travel of the laser beam.

5. The semiconductor inspection device of claim 1, wherein the first optical system is configured to move in the vertical direction to correspond to a vertical level of the semiconductor substrate stage.

6. The semiconductor inspection device of claim 5, wherein each of the channel layers further comprises a respective metal layer, and the controller is configured to:
calculate a ratio of first peak signal data of crystalline silicon to second peak signal data of amorphous silicon based on the depth of the semiconductor substrate, and
extract the degree of crystallinity by calculating a signal intensity based on a depth of the respective metal layer from the ratio.

7. The semiconductor inspection device of claim 6, wherein the degree of crystallinity is proportional to a signal strength of a bottom metal layer located on a bottom portion of the semiconductor substrate.

8. The semiconductor inspection device of claim 1, wherein the controller is configured to adjust a wavelength, amplitude, and wavenumber of the laser beam generated from the laser light source.

9. The semiconductor inspection device of claim 1, further comprising a second optical system arranged on a path of the Raman signal and configured to concentrate the Raman signal for the detector.

10. The semiconductor inspection device of claim 1, wherein the channel layers included in the semiconductor substrate are formed by metal-induced lateral crystallization (MILC).

11. A semiconductor inspection device comprising:
a semiconductor substrate including a plurality of channel layers;
a semiconductor substrate stage arranged on a bottom surface of the semiconductor substrate and moving the semiconductor substrate in a vertical direction;
a laser light source configured to generate a laser beam that is scanned onto the semiconductor substrate;
a first optical system spaced apart from a top surface of the semiconductor substrate in the vertical direction and configured to concentrate the laser beam at a confocal point;
a pin hole configured to allow a Raman signal to pass through the pin hole and block a noise signal, wherein the Raman signal is a laser beam scanned and scattered at the confocal point, and wherein the noise signal is a laser beam scanned and scattered at a point deviated from the confocal point;
a detector arranged at a position above the pin hole and configured to measure the Raman signal;
a controller configured to calculate a Raman spectrum through the Raman signal measured from the detector, wherein
the channel layers include amorphous silicon and crystalline silicon, and
the controller is further configured to extract peak signal data of the amorphous silicon and peak signal data of the crystalline silicon from among the Raman spectrum, and measure a degree of crystallinity based on a depth of the semiconductor substrate.

12. The semiconductor inspection device of claim 11, wherein the first optical system is configured to move in the vertical direction based on a vertical level of the semiconductor substrate stage, such that the confocal point of the laser beam is formed inside the semiconductor substrate.

13. The semiconductor inspection device of claim 11, wherein the degree of crystallinity is proportional to a magnitude of a ratio of a first peak signal data of crystalline silicon to a second peak signal data of amorphous silicon, based on the depth of the semiconductor substrate.

14. The semiconductor inspection device of claim 11, wherein
each of the channel layers further comprises a respective metal layer,
the controller is configured to extract peak signal data of the respective metal layer from among the Raman spectrum, and
the degree of crystallinity is proportional to a magnitude of the peak signal of the respective metal layer.

15. The semiconductor inspection device of claim 14, wherein the metal layer comprises at least one of nickel (Ni), aluminum (Al), titanium (Ti), and alloys thereof.

16. The semiconductor inspection device of claim 11, further comprising a second optical system arranged on a path of the Raman signal and configured to concentrate the Raman signal on the detector, wherein the second optical system includes at least one lens.

17. The semiconductor inspection device of claim 11, wherein the semiconductor substrate stage and the first optical system are configured to move in the vertical direction to a level at which a vertical level of the confocal point coincides with a vertical level of a bottom portion of the semiconductor substrate.

18. The semiconductor inspection device of claim 11, wherein the channel layers included in the semiconductor substrate are formed by metal-induced lateral crystallization.

19. A method of manufacturing a semiconductor device, the method comprising:
preparing a semiconductor substrate;
performing a semiconductor process on the semiconductor substrate;
inspecting a semiconductor generated through the semiconductor process, through a semiconductor inspection device; and
performing a subsequent semiconductor process on the semiconductor substrate, wherein
the semiconductor inspection device comprises:
a laser light source configured to generate a laser beam that is scanned onto the semiconductor substrate;
a first optical system spaced apart from a top surface of the semiconductor substrate in a vertical direction and configured to concentrate the laser beam at a confocal point;
a semiconductor substrate stage arranged on one side of the semiconductor substrate and configured to move the semiconductor substrate in the vertical direction,
a detector configured to measure a Raman signal from the laser beam scattered from the semiconductor substrate; and
a controller configured to calculate a Raman spectrum through the Raman signal measured from the detector, wherein
the semiconductor substrate includes a plurality of channel layers, and
the controller is configured to
extract one or more pieces of peak signal data of amorphous silicon and crystalline silicon included in the channel layers, from among the Raman spectrum,
calculate a ratio of a first peak signal data of crystalline silicon to a second peak signal data of amorphous silicon based on a depth of the semiconductor substrate, and
extract a degree of crystallinity by calculating a signal intensity based on a depth of a metal layer from the ratio.

20. The method of claim 19, wherein the inspecting of the semiconductor comprises:
as an operation of measuring the degree of crystallinity based on the depth of the semiconductor substrate:
obtaining the Raman spectrum for the semiconductor substrate through the detector and the controller;
vertically moving the semiconductor substrate stage and the first optical system;
determining whether the confocal point has reached a bottom portion of the semiconductor substrate;
when the confocal point reaches the bottom portion, post-processing the Raman spectrum through the controller, digitizing each piece of signal data of the Raman spectrum through the controller, and calculating the degree of crystallinity on the basis of the signal data; and
when the confocal point does not reach the bottom portion, repeating the obtaining of the Raman spectrum.
